(19) United States
(12) Patent Application Publication
(10) Pub. No.: US 2007/0018315 A1
(43) Pub. Date: Jan. 25, 2007

(54) Conductive adhesive composition

(76) Inventors: Hugh P. Craig, BUTTE, MT (US); Derril L. Steele, Cheyenne, WY (US)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(21) Appl. No.: 10/546,057

(22) PCT Filed: Sep. 18, 2003
(86) PCT No.: PCT/US03/29681

§ 371 Date: Jul. 31, 2006

(30) Foreign Application Priority Data
Mar. 18, 2003 (US) 10/392427

(51) Int. Cl. H01L 23/48

(52) U.S. Cl. 257/734

(57) ABSTRACT

A conductive adhesive composition includes a cross-linkable, adhesive component, a fluxing agent, and a conductive metal that has a surface on which is present a metal oxide. The adhesive component includes an epoxy resin and the fluxing agent includes a phenol. The phenol is reactive with the metal oxide on the surface of the conductive metal to at least partially remove the metal oxide from the surface of the conductive metal. As a result, a conductivity of the conductive adhesive composition is increased. The composition is particularly useful at interfaces between electrical or electronic components where it serves to physically mount and electrically connect necessary components and to continuously inhibit metal oxides from forming.

### BACKGROUND OF THE INVENTION

1. Field of the Invention

The subject invention generally relates to a conductive adhesive composition. More specifically, the subject invention relates to a conductive adhesive composition that is used, among other purposes, to physically mount and electrically connect electrical or electronic components to a printed circuit board (PCB) to form an electrical or electronic assembly.

2. Description of the Related Art

It is known that there is a desire to find suitable replacements for lead-based solder throughout the electrical or electronic assemblies industry. Many different lead-free systems, including conductive adhesive compositions that are free of lead, have been known in the art for some time. Generally, these conductive adhesive compositions are used to physically mount and electrically connect electrical or electronic components to a substrate, such as a PCB, to form an electrical or electronic assembly and many of these conductive adhesive compositions have been identified as potential replacements for the lead-based solder.

Unfortunately, many of the conductive adhesive compositions of the prior art cause additional problems relative to processing or suffer from other significant limitations.

First, it is known that typical processing of a PCB that incorporates lead-based solder requires processing temperatures of approximately 200-205° C. Many of the lead-free systems, including the conductive adhesive compositions of the prior art, require higher processing temperatures ranging up to 250-265° C. The increased processing temperatures at this level are frequently detrimental to other components causing melting and other damage. Therefore, other materials that are resistant to the increased processing temperatures must be used and these materials are commonly more expensive, which is undesirable.

Second, the resistance of even the best conductive adhesive compositions is not as good as the resistance of other forms of electrically connecting electrical components to PCBs, such as lead-based solder. For example, the popular silver and gold available throughout the industry have a resistance, after cure, of approximately 50 milliohms per square as compared to the resistance of lead-based solder of about 2.5 milliohms per square, after cure.

Third, the resistance of an electrical connection made with the conductive adhesive compositions of the prior art is subject to undesirable increase over time. Obviously, the increase in resistivity is detrimental to conductivity. By way of example, the conductive adhesive composition may serve to electrically connect (i) tinned leads of an electrical component such as an integrated circuit chip to (ii) copper pads upon a PCB. A thin film of the conductive adhesive, typically necessary to mechanically secure the electrical component to the PCB, is deposited and cured between the tinned leads and copper pads. Over a service life of the electrical or electronic assembly, oxygen within atmospheric air and moisture penetrate and permeate the cured conductive adhesive composition. The metal particles, which are incorporated into the adhesive composition for conductivity, are subject to oxidation. For instance, if the conductive metal particles are silver powder or silver flakes, a metallic oxide, specifically silver oxide, will form upon oxidation. Furthermore, the interfaces between the metal particles of the conductive adhesive composition and either the tinned leads or copper pads is particularly susceptible to oxidation because they are not constructed from noble metals. The build up of metallic oxide in the conductive adhesive compositions and at the interfaces over the service life of the electrical or electronic assembly causes resistance to progressively increase and conductivity to correspondingly decrease, ultimately reaching such levels as may cause erratic performance or outright failure of any electrical circuits in the assembly that are dependent upon the electrical connections of the conductive adhesive composition.

It is noteworthy that there have been several attempts in the prior art to mitigate the problems associated with the build-up of metallic oxides, all to no avail. K. Galleo et al., in a patent assigned to the Alpha Metal Division of Cookson, proposes adding very hard metal-coated ceramics to the conductive adhesive compositions so as to allow a mechanical connection of the interface. This approach has failed generally due to oxides developing between the metal particles and the electrical or electronic component.

In another approach, acids have been incorporated into the conductive adhesive compositions of the prior art. These acids initially clean and remove metallic oxides but, as the acids react into various components resin-like components of the composition, the acids become neutralized, and are thus no longer effective as a fluxing agent to flux the oxides from the metal particles. Furthermore, using excessive acid, in type or amount, may inhibit cure and will otherwise leave the conductive adhesive composition vulnerable to attack and degradation by moisture.

Due to the disadvantages associated with the conductive adhesive compositions of the prior art, including those described above, it would be desirable to provide a conductive adhesive composition that exhibits improved conductivity by having the ability to continuously remove, by fluxing, any metal oxides that arise in the conductive adhesive composition itself or at the interfaces between the electrical or electronic components where the composition is utilized.

### SUMMARY OF THE INVENTION AND ADVANTAGES

A conductive adhesive composition includes a conductive metal, a cross-linkable, adhesive component, and a fluxing agent. The conductive metal is present in an amount of from 50 to 90 parts by weight and has a surface on which is present a metal oxide, and cross-linkable, adhesive component is present in an amount of from 7 to 24 parts by weight and includes an epoxy resin.

The fluxing agent is present in an amount of from 1 to 20 parts by weight and includes a phenol reactive with the metal oxide on the surface of the conductive metal. This reaction causes the metal oxide to be at least partially removed from the surface of the conductive metal. As such, a conductivity of the conductive adhesive composition is increased.

The present invention not only contemplates placing a fluxing agent into a conductive adhesive composition so as to achieve low initial contact resistance, but also contemplates maintaining an environment suitable for continual fluxing throughout a life cycle of an electrical or electronic assembly in which the conductive adhesive composition is incorporated. In other words, the conductive adhesive composition establishes a long-persisting fluxing action, even throughout the cured stage of the composition. The conductive adhesive composition of the subject invention lowers resistivity thereby increasing conductivity by keeping electrical or electronic components (leads, pads, and the like) in electrical or electronic assemblies free from metal oxides.

Accordingly, the subject invention provides a conductive adhesive composition that exhibits improved conductivity by having the ability to continuously remove, by fluxing, any metal oxides that arise in the conductive adhesive composition itself or at the interfaces between the electrical or electronic components where the composition is utilized.

### BRIEF DESCRIPTION OF THE DRAWINGS

Other advantages of the present invention will be readily appreciated as the same becomes better understood by reference to the following detailed description when considered in connection with the accompanying drawings, which are for the purpose of illustration only and not to limit the scope of the invention in any way, wherein:

FIG. 1 is an illustration of a prior art electronics assembly focusing on the general use of a conductive adhesive composition in the making of an electrical connection wherein the electronics assembly has not aged;

FIG. 2 is an illustration of the prior art electronics assembly of FIG. 1 after aging where a metal oxide has formed throughout; and

FIG. 3 is an illustration of an electronics assembly using a conductive adhesive composition in accordance with the present invention following aging where no metal oxide has formed.

### DETAILED DESCRIPTION OF THE INVENTION

The following description is of the best mode presently contemplated for the carrying out of the invention. This description is made for the purpose of illustrating general principles of the invention, and is not to be talcen in a limiting sense. The scope of the invention is best determined by reference to the appended claims.

The subject invention discloses a conductive adhesive composition 26, or simply composition 26. Preferably, the composition 26 of the subject invention is used to physically mount and electrically connect electrical or electronic components 20 to a substrate 16, such as a non-conductive printed circuit board (PCB), to form an electrical or electronic assembly 24. PCBs 16 may, in particular, be made of a low melting temperature plastic, such as polystyrene, which is not ideal for heating at excessively high processing temperatures.

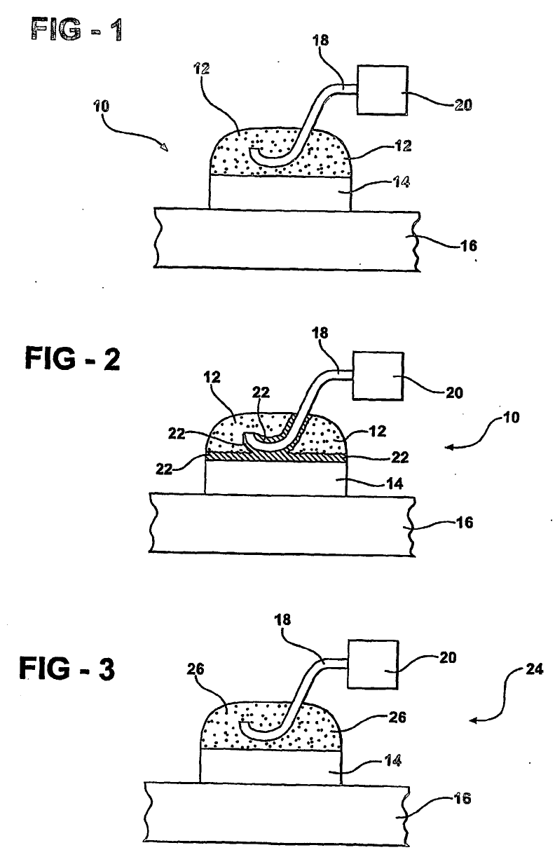

Referring particularly to FIG. 1, a prior art electronics assembly 10 is illustrated. FIG. 1 focuses on the general use of a prior art conductive adhesive composition 12 in the making of an electrical connection wherein the electronics assembly 10 has not aged, i.e., metal oxides 22 have not yet formed as described below with reference to FIG. 2. More specifically, an electrically conductive pad 14 is formed as a feature on a surface of a substrate, such as a PCB, 16. A lead 18 to an external electrical or electronic component 20 is permanently adhered to the pad 14 by action of the cured conductive adhesive composition 12 of the prior art. In FIG. 2, the prior art electronics assembly 10 of FIG. 1 has aged such that metal oxide 22 has formed throughout. More specifically, metal oxide 22 has formed at the interface between the composition 12 and the pad 14 and also at the interface between the composition 12 and the lead 18. The metal oxide 22 is of higher resistance than the metals that form either the pad 14 or the lead 18.

Referring now to FIG. 3, an electrical or electronics assembly 24 according to the subject invention is disclosed. The assembly 24 incorporates the composition 26 of the subject invention to establish an electrical connection between the lead 18 and the pad 14. More specifically, the composition 26 is deposited at an interface between the lead 18 of the electrical or electronic component 20 and the electrically conductive pad 14 on the substrate 16. In FIG. 3, aging has occurred and no metal oxide has formed. The composition 26 is then cured to electrically connect the lead 18 to the pad 14 as necessary.

The composition 26 includes a conductive metal, a cross-linkable adhesive component, and a fluxing agent. The conductive metal, which is typically a conductive metal particle, is present in the composition 26 in an amount of from 50 to 90, preferably from 70 to 85, parts by weight. The terminology ‘particle’ as utilized herein is intended to include conductive metal powders, conductive metal flakes, and the like.

Preferably, the conductive metal is selected from the group consisting of copper, silver, aluminum, gold, platinum, palladium, beryllium, rhodium, nickel, zinc, cobalt, iron, molybdenum, iridium, rhenium, mercury, ruthenium, osmium, and combinations thereof. More preferably, the conductive metal comprises a noble metal. In the most preferred embodiment of the subject invention, the noble metal is silver in particle, specifically flake, form. Two silver flakes that are suitable for use in the composition 26 of the present invention are Silver Flake 1 and Silver Flake 26 LV which are both commercially available from FerroMet. For descriptive purposes only, the remaining description will be in terms of the silver flake or flakes as the conductive metal. This form of description is for convenience and is not to be interpreted as limiting.

The conductive metal has a surface on which is present a metal oxide. As understood by those skilled in the art, the metal oxide forms on the surface as a result of an oxidation reaction of the conductive metal and oxygen and moisture in the air. The metal oxides tend to increase resistivity and are, therefore, relatively detrimental to conductivity, as compared to the pure conductive metal. In terms of the preferred silver flakes, each flake has a surface and the metal oxide is typically silver oxide. As described immediately above, although the metal oxide is conductive, it is not as conductive as the pure conductive metal, i.e., the pure un-oxidized silver flake in the preferred embodiment.

It is also noteworthy that the silver flakes may also have a lubricant on the surface. The lubricant, which is typically silver stearate, forms when stearic acid, which is used during milling of the silver flakes from silver powder, reacts with the surface of the silver flakes. It is believed that the fluxing agent of the present invention, which is described in greater detail below, also functions to remove the any lubricant from the surface of the silver flakes which further enhances a conductivity of the composition 26. The terminology ‘lubricant ’ as utilized herein generally refers to the silver stearate, but also to any stearic acid that remains from the milling of silver powder into silver flake.

The cross-linkable, adhesive component, hereinafter referred to as the adhesive component, is present in an amount of from 7 to 24, preferably from 11 to 19 parts by weight. The adhesive component is curable to physically adhere the electrical or electronic component 20 to the substrate 16, via the lead 18 and the pad 14.

The adhesive component includes an epoxy resin. Certain physical properties of the epoxy resin, specifically average epoxy functionality and epoxy equivalent, are important selection criteria for a ideal epoxy resin. More specifically, it is preferred that the epoxy resin have an average epoxy functionality of at least 2.5, more preferably of at least 3.0. It is also preferred that the epoxy resin has an epoxy equivalent of from 60 to 200, more preferably from 90 to 180, g/eq.

In the most preferred embodiment of the subject invention, the epoxy resin includes at least one of a triglycidyl of para-aminophenol and an epoxy phenol novolac (or novolak) resin. That is, in the most preferred embodiment, the epoxy resin can include a triglycidyl of para-aminophenol, an epoxy phenol novolac resin, or a blend of both epoxy resins. One suitable triglycidyl of para-aminophenol is Araldite® MY 0510 Epoxy Resin which is commercially available from Vantico, Inc., now a division of Huntsman of Salt Lake City, Utah. One suitable epoxy phenol novolac resin is Araldite® EPN 9850 Epoxy Resin which is also commercially available from Huntsman.

In an epoxy reaction, the epoxy resin cross-links. More specifically, upon heating the composition 26 at temperatures around 150° C. for approximately 3 to 15 minutes, the epoxy resin self cross-links thereby establishing ester linkages and curing. Heating the composition 26 can occur by any known heating mechanism including, but not limited to, conventional furnaces and ovens and microwave ovens, such as those that rely on variable frequency microwave radiation. In this epoxy reaction, a significant exotherm is realized and the conductive metal, the adhesive component, and the fluxing agent cure to form a cured conductive adhesive composition 26. It is understood by those skilled in the art that other chemical components including, but not limited to, amine- and/or carboxy-containing compounds, may be incorporated into the adhesive component to cross-link with the epoxy resin.

The adhesive component may optionally include a reactive diluent and a catalyst. In fact, although not required, preferred embodiments of the subject invention incorporate both the reactive diluent and the catalyst into the adhesive component along with the epoxy resin.

If included, the reactive diluent is preferably present in an amount of from 2 to 14 parts by weight and is preferably selected from the group consisting of acrylate monomers, methacrylate monomers, and combinations thereof. More preferably, the reactive diluent includes a monomer that is acrylate-based and at least di-functional. The most preferred reactive diluent is ethoxylated (4) pentaerythritol tetraacrylate which is commercially available as SR494 Ethoxylated (4) Pentaerythritol Tetraacrylate from Sartomer Company, Inc. of Exton, Pennsylvania. Other suitable monomers include mono-functional, di-functional, tri-functional, tetra-functional, and higher-functional monomers that may, or may not be, ethoxylated and propoxylated. Many such suitable monomers are also commercially available from Sartomer Company, Inc.

As used herein, the terminology ‘reactive diluent’ generally indicates a component that is used to reduce the relative concentration of an active material to achieve a desirable and beneficial effect. This particular reactive diluent is used in the adhesive component, along with the epoxy resin, to reduce the relative concentration of the epoxy reaction and moderate the effect of the epoxy reaction (e.g. to control viscosity upon epoxy cross-linling). Furthermore, it is believed that the exotherm from the epoxy reaction activates the reactive diluent, in the preferred embodiment the ethoxylated (4) pentaerythritol tetraacrylate, to supplemental cross-link with itself. In other words, it is believed that a second cross-linking reaction occurs. This second cross-linking reaction does not interact with the primary cross-linlcing associated with the epoxy resin of the adhesive component.

If included, the catalyst is preferably present in an amount of from 0.05 to 2 parts by weight and is preferably an imidazole. The most preferred type of imidazole for the adhesive component is 2-ethyl-4-methyl imidazole which is commercially available as IMICURE® EMI-24 from Air Products and Chemicals, Inc. of Allentown, Pennsylvania.

It is to be understood that, with respect to both the reactive diluent and the catalyst, wide ranging chemical alternatives are possible for incorporation into the adhesive component so long as the chemical alternatives are suitable for use along with the epoxy resin.

The composition 26 also includes the fluxing agent. The fluxing agent is present is an amount of from 1 to 20, preferably from 1 to 10, parts by weight. The fluxing agent includes a phenol that is reactive with the metal oxide on the surface of the conductive metal. As understood by those skilled in the art, a phenol is any one of a large class of aromatic organic compounds in which one or more hydroxy groups are attached directly to a benzene ring. At from 1 to 20 parts by weight, the fluxing agent, and specifically the phenol, does not degrade the adhesive component, i.e., the chemical backbone of the composition 26, in any manner. Instead, it is believed that the phenol functions to plasticize the epoxy resin thereby facilitating processing of the composition 26 and increasing flexibility and toughness of the cured composition 26.

The reactivity between the phenol of the fluxing agent and the metal oxide on the surface of the conductive metal at least partially removes the metal oxide from the surface of the conductive metal. With the metal oxide, which has a higher resistivity relative to the pure, i.e., un-oxidized, metal, removed from the conductive metal, the conductivity of the composition 26 is increased. Generally, the resistance of the composition 26 is reduced by at least 50% as compared to the conductive adhesive compositions, i.e., solder replacements, of the prior art, such as the solder replacement EPO-TEK® E2116-4 and E2116-5 which are both commercially available from Epoxy Technology of Billerica, MA. Both E2116-4 and E2116-5 have a resistivity of 0.0001 to 0.0005 ohm-cm which approximates to 40 to 200 milliohms per square. The reduction in resistivity of the composition of the subject invention, as compared to the conductive adhesive components of the prior art, results in a corresponding improvement in the conductivity. Generally, the resistance of the conductive adhesive composition 26 of the present invention is less than or equal to 15, preferably less than or equal to 10, milliohms per square. The terms ‘reactive with’ and ‘reactivity’ as utilized herein mean to react with or simply to clean, cleanse, or otherwise remove some amount of the metal oxide and/or the lubricant from the surface of the conductive metal.

The phenol incorporated into the composition 26 of the subject invention is acidic. As such, it is caustic, i.e., corrosive, relative to the silver oxide and functions, via continuous fluxing, to remove the silver oxide from the silver flake. The phenol remains in the composition 26 in predominantly unreacted form and functions as an unreacted fluxing agent to continuously remove oxidation, i.e., metal oxides, that arise on the electrical or electronic components 20, such as leads 18, pads 14, and the like. The phenol also functions to preclude the metal oxides from ever forming. By continuously fluxing and by precluding the metal oxides from ever forming, lower resistivity of the composition 26 and of any electronic assemblies 24 that incorporate the composition 26 can be preserved indefinitely.

The most preferred phenol for use in the composition 26 of the subject invention is nonylphenol (C₉H₁₉C₆H₄OH or C₁₅H₂₄O). However, it is to be understood that other phenols including, but not limited to, phenol, resorcinol, 4(tert-octyl) phenol, 2,5-di-tert-butyl-phenol, 2,6-diisopropylphenol, 2-(1-methylbutyl) phenol, 2-tert-butyl-6-methyl-phenol, and various Bisphenols, such as Bisphenol A, may be suitable for use as the fluxing agent in the composition 26 of the subject invention. Alternatively, the phenol may be further defined as a phenol of the formula Cₓ H_{y}C₆H₄OH, where x is from 3 to 12 and y is selected to saturate the phenol. For example, the phenol may be o-sec-butyphenol which is C₂H₅(CH₃)CHC₆H₄OH, o-tert-butylphenol which is (CH₃)₃CC₆H₄OH, p-tert-butylphenol which is (CH₃)₃CC₆H₄OH, p-tert-hexylphenol which is C₆H₁₃C₆H₄OH, dodecylphenol which is C₁₂H₂₅C₆H₄OH, and the like. Overall, the phenol is added in type and in amount so as to not degrade the epoxy resin of the adhesive component.

The composition 26 optionally includes a solvent for application of the composition 26 to the substrate 16. As such, it is ideal if the solvent is sufficient in type and in amount to dissolve the adhesive component and the fluxing agent into solution. If included in the composition 26, the solvent is preferably present in an amount of from 1 to 20 parts by weight for dissolving the adhesive component and the fluxing agent. Preferably, the type of solvent is selected from the group consisting of ethylene glycol monobutyl ether, diethylene glycol monobutyl ether, and combinations thereof. Ethylene glycol monobutyl ether is commercially available as butyl Cellosolve and diethylene glycol monobutyl ether is commercially available as butyl Carbitol, both from Dow Chemical of Midland, Michigan. Of course, it is to be understood that other solvents may be suitable for incorporation into the composition 26.

The following examples illustrating the conductive adhesive composition 26, as presented herein, are intended to illustrate and not to limit the invention. All references to parts by weight in the present application are based on 100 parts by weight of the conductive adhesive composition 26.

Referring to the following table, the conductive adhesive composition 26 was prepared by adding and reacting the following parts by weight (pbw). The pbw of each component outlined herein, especially the pbw of the conductive metal, the adhesive 10 component, and the fluxing agent are important for optimum reaction to cure and for lower resistivity, i.e., enhanced conductivity.

| | Example 1 | Example 1 | Example 2 | Example 2 | Example 3 | Example 3 |
|---|---|---|---|---|---|---|
| Component | (grams) | (pbw/100) | (grams) | (pbw/100) | (grams) | (pbw/100) |
| Adhesive Component | | | | | | |
| Epoxy Resin #1 | 40.0 | 5.90 | — | — | 60.0 | 8.61 |
| Epoxy Resin #2 | — | — | 40.0 | 5.92 | — | — |
| Reactive Diluent | 60.0 | 8.85 | 60.0 | 8.88 | 40.0 | 5.74 |
| Catalyst | 3.0 | .44 | 2.6 | .38 | 4.0 | .57 |
| Conductive Metal #1 | 565.0 | 83.33 | 563.0 | 83.33 | — | — |
| Conductive Metal #2 | 13 | — | — | — | 562.8 | 80.77 |
| Fluxing Agent | 10.0 | 1.48 | 10.0 | 1.49 | 30.0 | 4.31 |
| Solvent | 0.0 | 0.00 | 0.00 | 0.00 | 0.0 | 0.00 |
| TOTAL | 678.0 | 100.00 | 675.6 | 100.00 | 696.8 | 100.00 |

In the above tables:

Epoxy Resin #1 is Araldite® MY 0510 Epoxy Resin (Vantico, division of Huntsman);

Epoxy Resin #2 is Araldite® EPN 9850 Epoxy Resin (Vantico, division of Huntsman);

Reactive Diluent is SR494 Ethoxylated (4) Pentaerythiitol Tetraacrylate (Sartomer);

Catalyst is IMICURE® EMI-24 (Air Products and Chemicals, Inc.);

Conductive Metal #1 is Silver Flake 1 (FerroMet);

Conductive Metal #2 is Silver Flake 26 LV (FerroMet);

Fluxing Agent is nonyl phenol (Aldrich/Peninsula Polymers); and

Solvent is butyl Cellosolve (Dow Chemical).

The compositions of Examples 1 through 3 above were deposited on a substrate 16, specifically FR4, and heated to cure in an oven for 30 mins. X 150° C.

Obviously, many modifications and variations of the present invention are possible in light of the above teachings. The invention may be practiced otherwise than as specifically described within the scope of the appended claims.

1. A conductive adhesive composition comprising:
a conductive metal present in an amount of from 50 to 90 parts by weight and having a surface on which is present a metal oxide;
a cross-linkable, adhesive component present in an amount of from 7 to 24 parts by weight and comprising an epoxy resin and a reactive dilueut selected from the group consisting of acrylate monomers, methacrylate monomers, and combinations thereof, and
a fluxing agent present in an amount of from 1 to 20 parts by weight and comprising a phenol reactive with said metal oxide on said surface of said conductive metal to at least partially remove said metal oxide from said surface of said conductive metal thereby increasing a conductivity of said conductive adhesive composition,
wherein all parts by weight are based on 100 parts by weight of said conductive adhesive composition.

2. A conductive adhesive composition as set forth in claim 1 wherein said conductive metal is selected from the group consisting of copper, silver, aluminum, gold, platinum, palladium, beryllium, rhodium, nickel, zinc, cobalt iron, molybdenum, iridium, rhenium, mercury, ruthenium, osmium, and combinations thereof.

3. A conductive adhesive composition as set forth in claim 1 wherein said conductive metal comprises a noble metal.

4. A conductive adhesive composition as set forth in claim 3 wherein said noble metal comprises silver in particle form.

5. A conductive adhesive composition as set forth in claim 1 wherein said conductive metal is present in an amount of from 70 to 85 parts by weight.

6. A conductive adhesive composition as set forth in claim 1 wherein said epoxy resin has an average epoxy functionality of at least 2.5.

7. A conductive adhesive composition as set forth in claim 1 wherein said epoxy resin has an average epoxy functionality of at least 3.0.

8. A conductive adhesive composition as set forth in claim 1 wherein said epoxy resin has an epoxy equivalent of from 60 to 200 g/eq.

9. A conductive adhesive composition as set forth in claim 1 wherein said epoxy resin has an epoxy equivalent of from 90 to 180 g/eq.

10. A conductive adhesive composition as set forth in claim 1 wherein said epoxy resin comprises at least one of a triglycidyl of para-aminophenol and an epoxy phenol novolac resin.

11. A conductive adhesive composition as set forth in claim 1 wherein said adhesive component is present in an amount of from 11 to 19 parts by weight

12. (Canceled)

13. (Canceled)

14. A conductive adhesive composition as set forth in claim 1 wherein said reactive diluent comprises a monomer that is acrylate-based and at least di-functional.

15. A conductive adhesive composition as set forth in claim 14 wherein said monomer comprises ethoxylated (4) pentaerythritol tetraacrylate.

16. A conductive adhesive composition as set forth in claim 1 wherein said cross-linkable, adhesive component further comprises a catalyst.

17. A conductive adhesive composition as set forth in claim 16 wherein said catalyst comprises an imidazole.

18. A conductive adhesive composition as set forth in claim 1 wherein said phenol comprises nonylphenol.

19. A conductive adhere composition as set firth in claim 1 wherein said phenol comprises a Bisphenol.

20. A conductive adhesive composition as set forth in claim 1 wherein said phenol comprises resorcinol.

21. A conductive adhesive composition as set forth in claim 1 wherein said phenol is further defined as a phenol of the formula Cₓ H_{y}C₆H₄OH, where x is from 3 to 12 and y is selected to saturate said phenol.

22. A conductive adhesive composition as set forth in claim 1 wherein said phenol is acidic.

23. A conductive adhesive composition as set forth in claim 1 wherein said fluxing agent is present in an amount of from 1 to 10 parts by weight.

24. A conductive adhesive composition as set forth in claim 1 further comprising a solvent present in an amount of from 1 to 20 parts by weight for dissolving said cross-linkable, adhesive component and said fluxing agent.

25. A conductive adhesive composition as set forth in claim 24 wherein said solvent is selected from the group consisting of ethylene glycol monobutyl ether, diethylene glycol monobutyl ether, and combinations thereof.

26. A conductive adhesive composition as set forth in claim 1 having a resistance less than or equal to 15 milliohms per square.

27. A substrate having an electrical connection formed from said conductive adhesive composition of claim 1.

28. A conductive adhesive composition consisting essentially of:
a conductive metal present in an amount of from 50 to 90 parts by weight and having a surface on which is present a metal oxide;
a cross-linkable, adhesive component present in an amount of from 7 to 24 parts by weight and comprising;
an epoxy resin,
a reactive diluent selected from the group consisting of acrylate monomers, methacrylate monomers, and combinations thereof, and
a catalyst, and
a fluxing agent present m an amount of from 1 to 20 parts by weight and comprising a phenol reactive with said metal oxide on said surface of said conductive metal to at least partially remove said metal oxide from said surface of said conductive metal thereby increasing a conductivity of said conductive adhesive composition,
wherein all parts by weight are based on 100 parts by weight of said conductive adhesive composition.

29. A conductive adhesive composition as set forth in claim 28 wherein said epoxy resin comprises at least one of a triglycidyl of para-aminophenol and an epoxy phenol novolac resin.

30. (Canceled)

31. A conductive adhesive composition as set forth in claim 28 wherein said reactive diluent comprises a monomer that is acrylate-based and at least di-functional.

32. A conductive adhesive composition as set forth in claim 28 wherein sad catalyst comprises an imidazole.

33. A conductive adhesive composition as set forth in claim 28 wherein said phenol comprises nonylphenol.

34. A conductive adhesive composition as set forth in claim 28 further comprising a solvent present in an amount of from 1 to 20 parts by weight for dissolving said cross-linkable, adhesive component and said fluxing agent.
